(19) United States
(12) Patent Application Publication
(10) Pub. No.: US 2015/0062798 A1
(43) Pub. Date: Mar. 5, 2015

(54) RACK SERVER SLIDE-IN MODULE

(71) Applicant: Fujitsu Technology Solutions Intellectual Property GmbH, München (DE)

(72) Inventors: Bernhard Kannler, Augsburg (DE); Frank Schubert, Graben (DE)

(73) Assignee: Fujitsu Technology Solutions Intellectual Property GmbH, München (DE)

(21) Appl. No.: 14/391,196

(22) PCT Filed: Mar. 14, 2013
(86) PCT No.: PCT/EP2013/055254

§ 371 Date: Oct. 8, 2014

(30) Foreign Application Priority Data
Apr. 11, 2012 (DE) 10 2012 103 113.4

(51) Int. Cl. H05K 7/14; H05K 7/20

(52) U.S. Cl. CPC H05K 7/1461; H05K 7/20145
USPC 361/679.32

(57) ABSTRACT

A rack server slide-in module for an installation height of one rack unit, with a front face, a rear face, two lateral walls, a base wall, a cover wall and a mounting slot for a dual-slot expansion card, in which either a single-slot or a dual-slot expansion card is received, wherein an air inlet aligned with the mounting slot for the expansion card is provided on the front face of the rack server slide-in module and fans are arranged side by side between the air inlet and the expansion slot for the expansion card, the fans generating an increased flow pressure of the cooling air onto the mounting slot of the expansion card.

### TECHNICAL FIELD

This disclosure relates to a rack server slide-in module with an installation height of one rack unit, with a front face, a rear face, two lateral walls, a base wall and a cover wall and also a mounting slot for a dual-slot expansion card, in which either a single-slot or a dual-slot expansion card is received.

### BACKGROUND

Rack server slide-in modules are in demand preferably in the height of one rack unit, corresponding to 44.45 mm, for installation in what are known as 19″ racks. The advantage of the rack server slide-in modules of one rack unit is that a relatively large number of such rack server slide-in modules can be accommodated in a 19″ rack and, if necessary, the 19″ rack can be fitted with further rack server slide-in modules.

Typical workstation computers, which were previously used preferably in the form of tower or floor-standing units, are now in demand likewise in the form of rack server slide-in modules. Workstation computers are generally used for graphics-intensive applications such as CAD (Computer Aided Design) or video-editing.

Therefore, the use of high-end graphics cards is necessary.

High-end graphics cards have an overall height of two slots, that is, 2×19.5=39 mm. The chassis of a rack server slide-in module for a dividing grid of one rack unit has an overall height of 42.8 mm, as the 44.45 mm for one rack unit cannot be utilized to the fullest extent. The chassis of a rack server slide-in module has a cover wall of 1 mm thickness and a base wall of 1.2 mm thickness and, therefore, only 1.6 mm clearance remains for the installation of the dual-slot expansion card in a rack server slide-in module of one rack unit. An expansion card, for example, in the form of a graphics card, has a thermal power loss of up to 200 W and, therefore, has to be cooled accordingly.

It could therefore be helpful to integrate a dual-slot expansion card in a rack server slide-in module having a height of one rack unit.

### SUMMARY

We provide a rack server slide-in module for an installation height of one rack unit, with a front face, a rear face, two lateral walls, a base wall, a cover wall and a mounting slot for a dual-slot expansion card, in which either a single-slot or a dual-slot expansion card is received, wherein an air inlet aligned with the mounting slot for the expansion card is provided on the front face of the rack server slide-in module and fans are arranged side by side between the air inlet and the expansion slot for the expansion card, the fans generating an increased flow pressure of the cooling air onto the mounting slot of the expansion card.

We also provide a rack server slide-in module for an installation height of one rack unit, with a front face, a rear face, two lateral walls, a base wall, a cover wall and a mounting slot for a dual-slot expansion card, in which either a single-slot or a dual-slot expansion card is received, wherein an air inlet aligned with the mounting slot for the expansion card is provided on the front face of the rack server slide-in module and fans are arranged side by side between the air inlet and the expansion slot for the expansion card, the fans generating an increased flow pressure of the cooling air onto the mounting slot of the expansion card, and wherein the expansion card is received in an air guide frame mounted in the expansion slot.

We further provide a rack server slide-in module for an installation height of one rack unit, with a front face, a rear face, two lateral walls, a base wall, a cover wall and a mounting slot for a dual-slot expansion card, in which either a single-slot or a dual-slot expansion card is received, wherein an air inlet aligned with the mounting slot for the expansion card is provided on the front face of the rack server slide-in module and fans are arranged side by side between the air inlet and the expansion slot for the expansion card, the fans generating an increased flow pressure of the cooling air onto the mounting slot of the expansion card, and wherein the air guide frame has on the rear face lying in a flow direction of a slot panel with an air outlet.

We further provide a rack server slide-in module for an installation height of one rack unit, with a front face, a rear face, two lateral walls, a base wall, a cover wall and a mounting slot for a dual-slot expansion card, in which either a single-slot or a dual-slot expansion card is received, wherein an air inlet aligned with the mounting slot for the expansion card is provided on the front face of the rack server slide-in module and fans are arranged side by side between the air inlet and the expansion slot for the expansion card, the fans generating an increased flow pressure of the cooling air onto the mounting slot of the expansion card, and wherein a further air outlet with air outlet openings is provided at the rear face between slot panel and the lateral wall of the rack server slide-in module.

We further provide a rack server slide-in module for an installation height of one rack unit, with a front face, a rear face, two lateral walls, a base wall, a cover wall and a mounting slot for a dual-slot expansion card, in which either a single-slot or a dual-slot expansion card is received, wherein an air inlet aligned with the mounting slot for the expansion card is provided on the front face of the rack server slide-in module and fans are arranged side by side between the air inlet and the expansion slot for the expansion card, the fans generating an increased flow pressure of the cooling air onto the mounting slot of the expansion card, wherein a further air outlet with air outlet openings is provided at the rear face between slot panel and the lateral wall of the rack server slide-in module, and wherein the air guide frame receives the expansion card so that it is spaced from the lateral wall of the rack server slide-in module and an air deflector can be received in different positions in the space between the lateral wall of the rack server slide-in module and the expansion card, and the air deflector directs the cooling air to the expansion card.

We further provide a rack server slide-in module for an installation height of one rack unit, with a front face, a rear face, two lateral walls, a base wall, a cover wall and a mounting slot for a dual-slot expansion card, in which either a single-slot or a dual-slot expansion card is received, wherein an air inlet aligned with the mounting slot for the expansion card is provided on the front face of the rack server slide-in module and fans are arranged side by side between the air inlet and the expansion slot for the expansion card, the fans generating an increased flow pressure of the cooling air onto the mounting slot of the expansion card, wherein the air guide frame has on the rear face lying in a flow direction of a slot panel with an air outlet, and wherein the expansion card has its own fan which draws in air from below and blows it out to the rear via the air outlet.

We further provide a rack server slide-in module for an installation height of one rack unit, with a front face, a rear face, two lateral walls, a base wall, a cover wall and a mounting slot for a dual-slot expansion card, in which either a single-slot or a dual-slot expansion card is received, wherein an air inlet aligned with the mounting slot for the expansion card is provided on the front face of the rack server slide-in module and fans are arranged side by side between the air inlet and the expansion slot for the expansion card, the fans generating an increased flow pressure of the cooling air onto the mounting slot of the expansion card, and wherein three fans are arranged in a fan bank extending transversely across the rack server slide-in module and the further fans in the fan bank generate a weaker flow of cooling air than the fans.

We further provide a rack server slide-in module for an installation height of one rack unit, with a front face, a rear face, two lateral walls, a base wall, a cover wall and a mounting slot for a dual-slot expansion card, in which either a single-slot or a dual-slot expansion card is received, wherein an air inlet aligned with the mounting slot for the expansion card is provided on the front face of the rack server slide-in module and fans are arranged side by side between the air inlet and the expansion slot for the expansion card, the fans generating an increased flow pressure of the cooling air onto the mounting slot of the expansion card, and wherein the expansion card is a PCI dual-slot graphics card.

### BRIEF DESCRIPTION OF THE DRAWINGS

FIG. 1 shows a rack server slide-in module in an oblique view from above.

FIG. 2 shows an enlarged partial view of the left-hand region of the rack server slide-in module from FIG. 1.

FIG. 3 shows the region from FIG. 2 in a view from above.

FIG. 4 shows the region from FIG. 2 in an oblique view from behind with air guide frame and expansion card removed.

FIG. 5 shows an oblique view of the air guide frame and the expansion card.

FIG. 6 shows the air guide frame and the expansion card in a view from below.

### LIST OF REFERENCE SIGNS

1 Front face
2 Rear face
3 Lateral wall
4 Base wall
5 Hard drives
6 Optical drive
7a-7c Air inlet
8 Fan bank
9a-9g Fan
10 Motherboard
11 Power supply
12 Power supply fan
13 Heat sink
14 Mounting slot for the expansion card
15 Dual-slot expansion card
16 Air guide frame
17 Air deflector
18 Further threaded bores for fastening the air deflector
19 Slot panel
20 Plug
21 Air outlet in slot panel
22 Air outlet next to slot panel
23 Graphics card fan

### DETAILED DESCRIPTION

We provide an air inlet aligned with the mounting slot for the expansion card on the front face of the rack server slide-in module, an air outlet aligned behind the mounting slot for the expansion card is provided on the rear face of the rack server slide-in module, and fans are arranged side by side between the air inlet and the mounting slot for the expansion card, the fans generating an increased flow pressure of the cooling air onto the mounting slot of the expansion card.

Through the aligned arrangement of the air inlet, the fans, which generate an increased flow pressure of the cooling air onto the mounting slot of the expansion card, and the air outlet, the expansion card received in the mounting slot is supplied with sufficient cooling air so that even a thermal power loss of 200 W can still be dissipated.

A preferred construction provides for the expansion card to be received in an air guide frame mounted in the mounting slot. The air guide frame ensures that the flow generated by the fans does not flow away to the side, but acts directly on the expansion card in the air guide frame.

Preferably, the air guide frame has on the rear face a slot panel with openings to let air out. To improve air extraction, further air outlet openings can be provided at the rear face between slot panel and the lateral wall of the rack server slide-in module.

Preferably, the air guide frame receives the expansion card so that it is spaced from the lateral wall of the rack server slide-in module and an air deflector, which can be mounted in different positions and thus additionally directs cooling air to the expansion card, is provided in this space between the lateral wall of the rack server slide-in module and the expansion card. The air deflector, therefore, prevents a bypass flow and additionally feeds the cooling air to the expansion card.

This is especially advantageous when the expansion card is actively cooled, that is, has its own fan which draws in air from below and blows it out to the rear. To ensure sufficient throughput of cooling air even with this dedicated fan of the expansion card, it is imperative for the air fed in via the narrow gap at the top and bottom face of the expansion card to be blown in under pressure so that the expansion card fan can draw in sufficient air via the narrow gap for cooling purposes and blow it out to the rear.

Preferably, the rack server slide-in module has a fan bank extending transversely across the rack server slide-in module, in which three fans are arranged in front of the mounting slot for the expansion card, and the remaining fans generate a flow of cooling air for the motherboard, the power supply and the other components on the motherboard. The fans in the fan bank are preferably controlled such that the three fans in front of the mounting slot for the expansion card preferably generate a much stronger flow than the remaining fans in the fan bank.

The module is particularly effective when the expansion card is in the form of a dual-slot expansion card and this is in the form of a graphics card since a lot of lost heat has to be dissipated.

Turning now to the Drawings, elements having the same construction and function are provided with the same reference signs and are not separately explained.

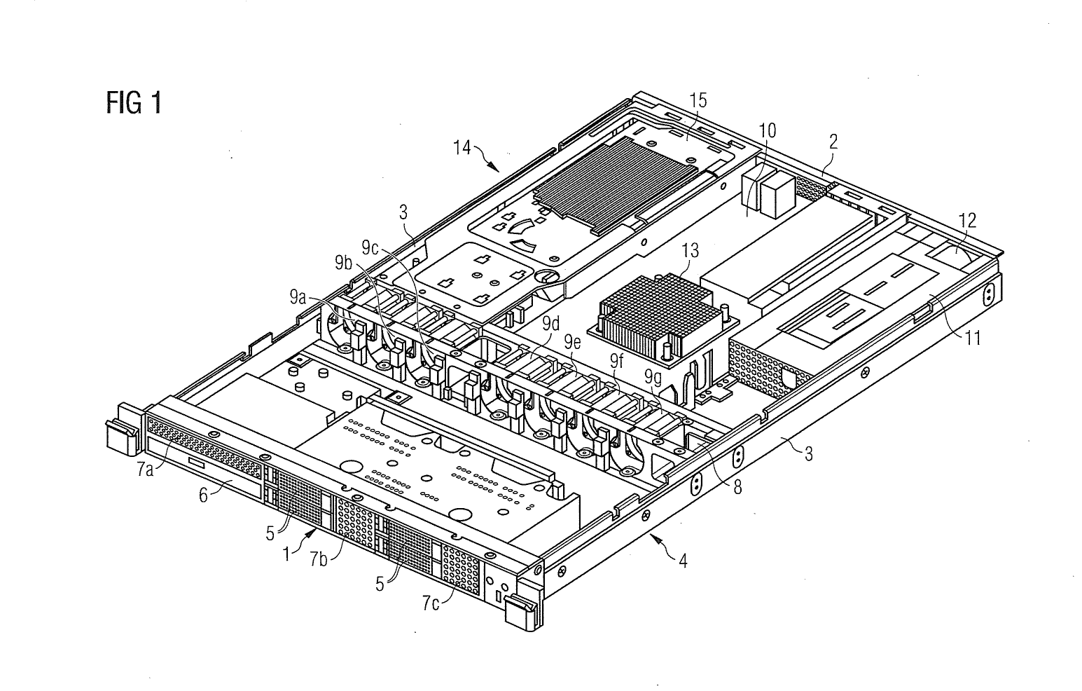

FIG. 1 shows a rack server slide-in module with a height of about one rack unit.

The rack server slide-in module is shown in an oblique view from the front and from above, the cover wall already having been removed.

The rack server slide-in module comprises a front face 1, a rear face 2, two lateral walls 3 and a base wall 4. In sum terms, the rack server slide-in module is not fully one rack unit, equal to 44.5 mm, high, but in the closed state with the cover wall is 42.8 mm. The cover wall is 1 mm and the base wall is about 1.2 mm.

On the front face 1 the rack server slide-in module has four hard drives 5, a DVD drive or optical drive 6 and air inlets 7a, 7b and 7c, the air inlet 7a being constructed above the optical drive 6 and across the entire width of the optical drive 6.

Behind the hard drives 5, a fan bank 8 in which the fans 9a to 9g are received in the mounting slots 1 to 7 extends transversely across the rack server slide-in module. A motherboard 10 and next to it a power supply 11 are arranged behind the fan bank 9. The power supply 11 has its own fan 12, which draws in air from the front face 1 and blows it out to the rear. For this reason a corresponding free space is provided in the fan bank 8 next to the mounting slot 7 for the fan 9g.

Customary electronic components such as the CPU with a heat sink 13 mounted thereon, are arranged on the motherboard 10.

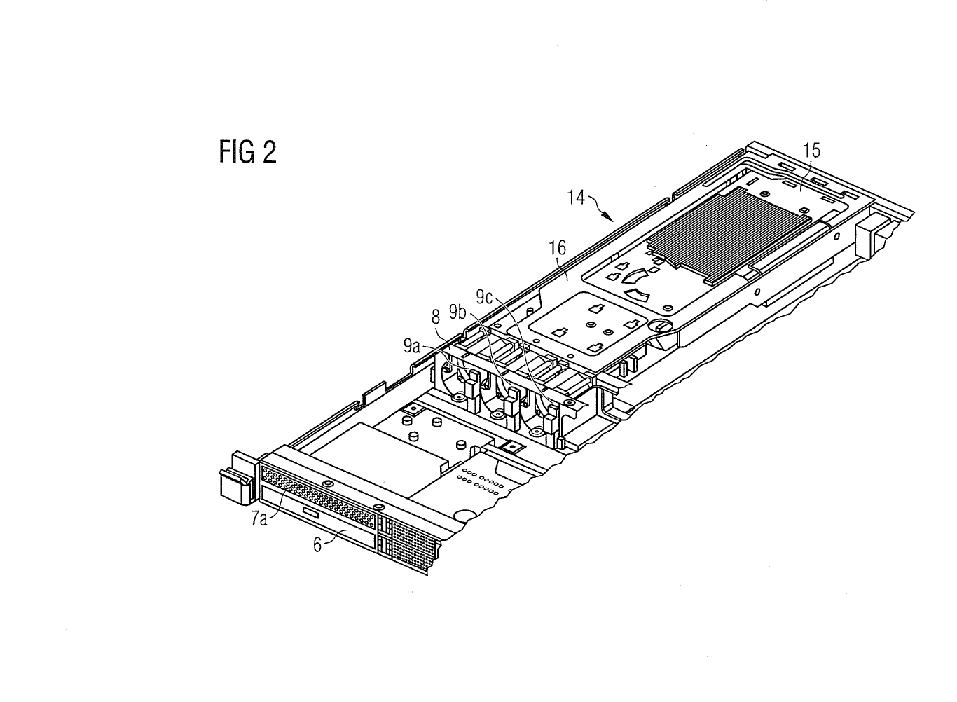

Next to the motherboard 10 and behind the fan bank 8 a mounting slot 14 is provided for a dual-slot graphics card 15. This region is illustrated in an enlarged form in FIG. 2 and is explained hereafter with reference to FIG. 2. The dual-slot graphics card 15 is received in an air guide frame 16 and arranged longitudinally in alignment with and behind the fans 9a to 9c. Through the air inlet 7a above the optical drive 6, the fans 9a to c blow air at increased pressure into the air guide frame 16 and the expansion card 15 is thus force-cooled. This is very important as the dual-slot expansion card 15 takes up virtually the entire height in a rack server slide-in module of one rack unit and only a small gap remains at the top face and bottom face to inject the cooling air. The air guide frame 16 ensures that the cooling air acts mainly on the expansion card 15 and does not flow away to the side.

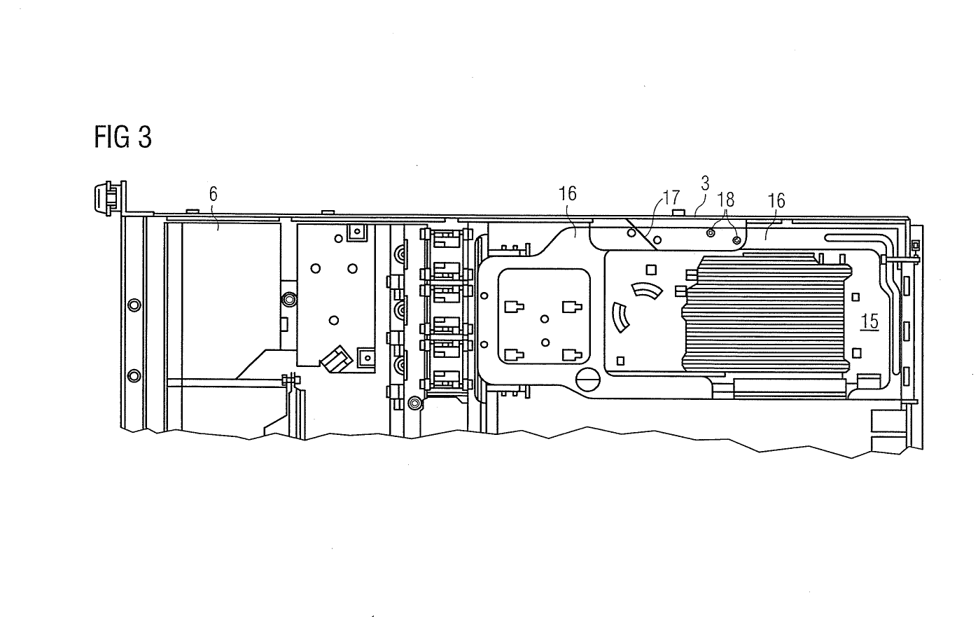

FIG. 3 shows the region from FIG. 2 in a view from above. An area of the air guide frame 16 in the region between the lateral wall 3 and expansion card 15 has been broken open to show that between the expansion card 15 and the lateral wall 3 there is a certain space in which an air deflector 17 is mounted. This directs the cooling air generated by the fans 9a to c at increased pressure towards the expansion card 15, not allowing any bypass flow.

Next to the mounted position of the air deflector 17 there is a second mounting position, only the bores 18 associated therewith being illustrated. This second position is needed for other types of expansion cards.

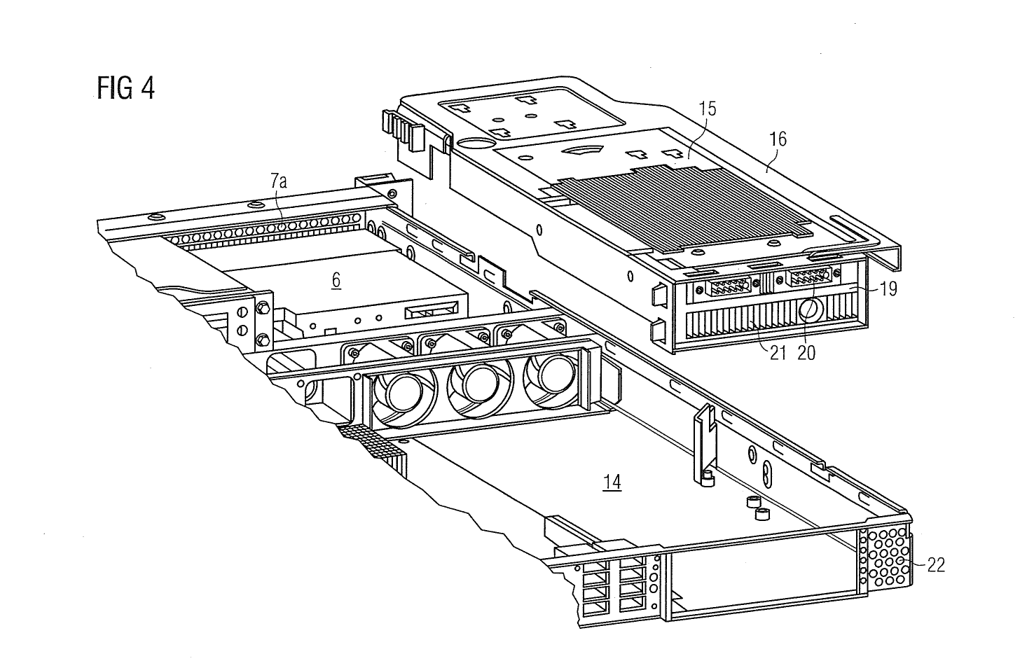

FIG. 4 shows the region from FIGS. 2 and 3 in an oblique view from the rear, the expansion card 15 and the air guide frame 16 being illustrated in the unmounted state.

The dual-slot expansion card 15 has on the rear face thereof a slot panel 19, connector plugs 20 being provided in the upper region and air outlet openings 21 to blow out the cooling air being provided in the lower region. On the rear face 2 of the rack server slide-in module further air outlet openings 22 are provided next to the slot panel 19 to allow the cooling air injected via the fans 9a to c to flow out more easily.

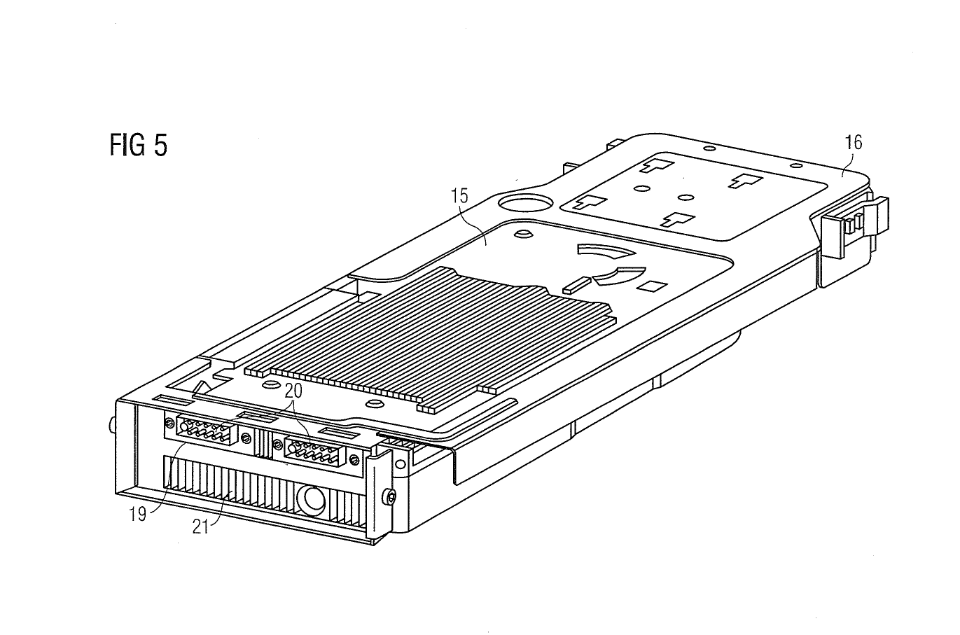

FIG. 5 shows the dual-slot expansion card 15 in an oblique view from behind, the air outlet openings in the slot panel 19 again being illustrated.

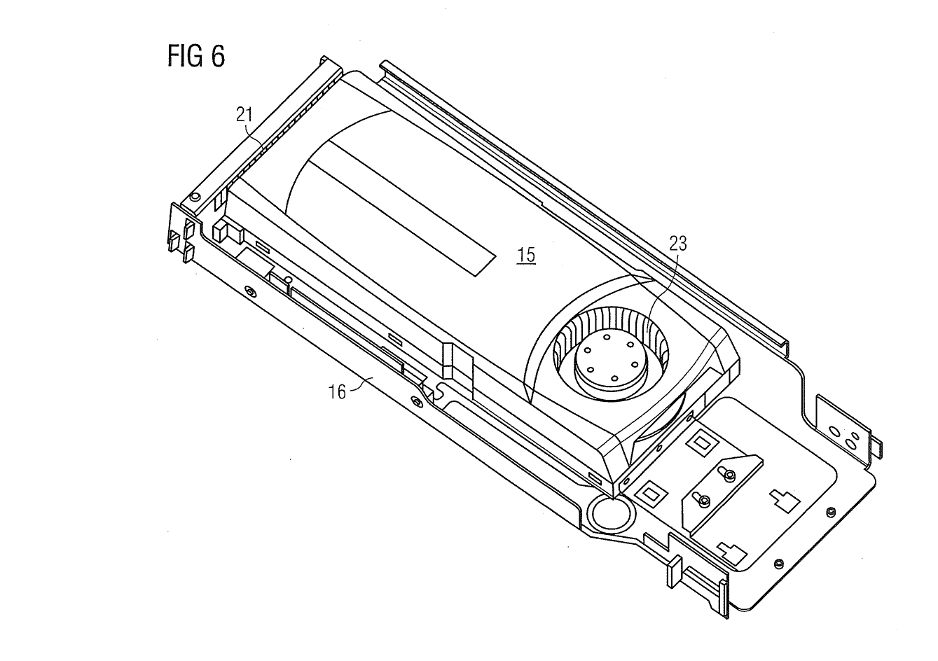

FIG. 6 shows the view from FIG. 5 from above, the dual-slot expansion card 15 having its own fan 22 which actively blows the cooling air to the air outlet 21 in the slot panel 19 and, hence, actively cools the dual-slot expansion card 15. The fan is mounted slightly inset from the underside of the expansion card 15 so that in the air intake region a somewhat larger gap than the 0.8 mm is available for admitting the air for the fan 22.

A single-slot expansion card can also be received in the air guide frame 16, but here the heat dissipation is less critical than it is with the installation of a dual-slot expansion card 15.

1-8. (canceled)

9. A rack server slide-in module for an installation height of one rack unit, with a front face, a rear face, two lateral walls, a base wall, a cover wall and a mounting slot for a dual-slot expansion card, in which either a single-slot or a dual-slot expansion card is received,
wherein
an air inlet aligned with the mounting slot for the expansion card is provided on the front face of the rack server slide-in module and fans are arranged side by side between the air inlet and the expansion slot for the expansion card, said fans generating an increased flow pressure of the cooling air onto the mounting slot of the expansion card.

10. The rack server slide-in module according to claim 9, wherein the expansion card is received in an air guide frame mounted in the expansion slot.

11. The rack server slide-in module according to claim 9, wherein the air guide frame has on the rear face lying in a flow direction of a slot panel with an air outlet.

12. The rack server slide-in module according to claim 9, wherein a further air outlet with air outlet openings is provided at the rear face between slot panel and the lateral wall of the rack server slide-in module.

13. The rack server slide-in module according to claim 12, wherein the air guide frame receives the expansion card so that it is spaced from the lateral wall of the rack server slide-in module and an air deflector can be received in different positions in the space between the lateral wall of the rack server slide-in module and the expansion card, and the air deflector directs the cooling air to the expansion card.

14. The rack server slide-in module according to claim 11, wherein the expansion card has its own fan which draws in air from below and blows it out to the rear via the air outlet.

15. The rack server slide-in module according to claim 9, wherein three fans are arranged in a fan bank extending transversely across the rack server slide-in module and the further fans in the fan bank generate a weaker flow of cooling air than the fans.

16. The rack server slide-in module according to claim 9, wherein the expansion card is a PCI dual-slot graphics card.
